(19) United States
(12) Patent Application Publication
(10) Pub. No.: US 2005/0167745 A1
(43) Pub. Date: Aug. 4, 2005

(54) Semiconductor device with element isolation region and method of fabricating the same

(75) Inventors: Katsuhiro Ishida, Yokkaichi (JP); Katsuya Ito, Yokkaichi (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: KABUSHIKI KAISHA TOSHIBA, Tokyo (JP)

(21) Appl. No.: 10/992,722

(22) Filed: Nov. 22, 2004

(30) Foreign Application Priority Data
Nov. 20, 2003 (JP) 2003-391016

(51) Int. Cl. H01L 29/76

(52) U.S. Cl. 257/329

(57) ABSTRACT

A semiconductor device includes a semiconductor substrate having an upper face, a plurality of trenches formed in the semiconductor substrate, an element isolating film embedded in each trench and having a top located higher than the upper face of the semiconductor substrate, a gate insulating film formed on the semiconductor substrate so as to be located between the element isolating films adjacent to each other, and a gate electrode formed on the gate insulating film and having a top located higher than the top of the element isolating film. The element isolating film has a recess formed on the top thereof so that the recess extends toward the semiconductor substrate.

### CROSS-REFERENCE TO RELATED APPLICATION

This application claims priority to Japanese patent application No. 2003-391016, filed Nov. 20, 2003, the content of which is incorporated herein by reference.

### BACKGROUND OF THE INVENTION

1. Field of the Invention

The present invention relates to a semiconductor device provided with an element isolation region and a method of fabricating the same.

2. Description of the Related Art

FIG. 15A schematically illustrates a sectional structure of a typical non-volatile memory 1. The non-volatile memory 1 has a structure disclosed in JP-A-9-246500 and JP-A-2002-368077. The non-volatile memory 1 comprises a semiconductor substrate 2 and a gate oxide (gate insulating film) 3 formed on the semiconductor substrate 2. First and second polycrystalline silicon films 4 and 5 each serving as a floating gate electrode are formed on the gate oxide 3 in stack. An oxide-nitride-oxide (ONO) film 6 is formed on the second polycrystalline silicon film 5.

A third polycrystalline silicon film 7 constituting a control gate electrode is formed on the ONO film 6. A tungsten silicide (WSi) film 8 is formed on the third polycrystalline silicon film 7. A gate electrode 9 comprises the first and second polycrystalline silicon films 4 and 5, ONO film 6, third polycrystalline silicon film 7 and Wsi film 8. Memory cells are isolated from one another by a shallow trench isolation (STI) 10.

In semiconductor devices, a minimum pattern width defined by the circuit design rules have been reduced for the purpose of high integration year by year. For example, in non-volatile memories such as NAND flash memories, a distance between memory cells adjacent to each other has been shortened by the influence of reduction in the circuit design rules, whereupon a parasitic capacitance has been increased. When the parasitic capacitance between memory cells adjacent to each other is increased, each memory cell tends to be influenced by the adjacent one due to the Yupin Effect. Consequently, an operating voltage is shifted such that a desired operating voltage property cannot be obtained.

Further, reduction in the circuit design rules sometimes reduces a coupling ratio (Cᵣ={Cₒₙₒ÷(Cₒₙₒ+Cₒₓ)}) which is one index of the memory cell characteristic and/or a capacity value of a floating gate. The value of Cₒₙₒ indicates a capacity value between the polycrystalline silicon films 5 and 7 opposed to each other with the ONO film 6 being interposed therebetween. The value of Cₒₓ indicates a capacity value between the semiconductor substrate 2 and the first polycrystalline silicon film 4 with the gate oxide 3 being interposed therebetween.

The polycrystalline silicon films 4 and 5 constituting the floating gate electrode structure are each formed into a T-shape in order that the coupling ratio may be increased. As a result, an opposed surface area is ensured between the polycrystalline silicon films 4 and 5 and the ONO film 6. However, it becomes more difficult to ensure a necessary surface area as the distance between the adjacent memory cells becomes short.

To overcome the foregoing problem, the prior art has proposed forming the ONO film 6 on the side of the polycrystalline silicon film 4, instead of employment of the T-shaped structure, thereby ensuring the surface area. An aspect ratio is increased when a height of the polycrystalline silicon film 4 is increased in order that the surface area may be increased. Increase in the aspect ratio causes failure in embedding in a process of embedding the STI 10, thus adversely affecting formation of a circuit pattern. Accordingly, increasing the height of the floating gate electrode is not practical. That is, with reduction in the circuit design rules, a desired coupling ratio and capacitor value of the floating gate cannot be ensured, whereupon there is a possibility of causing failure in the device operation.

### BRIEF SUMMARY OF THE INVENTION

Therefore, an object of the present invention is to provide a semiconductor device which can restrain increase in the parasitic capacitance with reduction in the distance between the memory cells adjacent to each other and which can ensure a desired coupling ratio and capacitance value of the capacitor, and a method of fabricating the semiconductor device.

The present invention provides a semiconductor device comprising a semiconductor substrate having an upper face, a plurality of trenches formed in the semiconductor substrate, an element isolating film embedded in each trench and having a top located higher than the upper face of the semiconductor substrate, a gate insulating film formed on the semiconductor substrate so as to be located between the element isolating films adjacent to each other, and a gate electrode formed on the gate insulating film and having a top located higher than the top of the element isolating film, wherein the element isolating film has a recess formed on the top thereof so that the recess extends toward the semiconductor substrate.

The invention also provides a method of fabricating a semiconductor device, comprising forming a trench in a semiconductor substrate, embedding an insulating film in the trench, and forming a recess in a top of the insulating film.

The invention further provides a method of fabricating a semiconductor device, comprising forming a gate insulating film on a semiconductor substrate, forming a trench in the semiconductor substrate and the gate insulating film so that a gate electrode is formed on the gate insulating film, embedding an insulating film in the trench, and forming a recess in a top of the insulating film.

### BRIEF DESCRIPTION OF THE DRAWINGS

Other objects, features and advantages of the present invention will become clear upon reviewing the following description of the embodiment with reference to the accompanying drawings, in which:

FIG. 1 is a cross section of a semiconductor device in accordance with an embodiment of the present invention;

FIG. 2 is a cross section of the semiconductor device at a first stage in a fabricating process of the fabrication method;

FIG. 3 is a cross section of the semiconductor device at a second stage in the fabricating process of the fabrication method;

FIG. 4 is a cross section of the semiconductor device at a third stage in the fabricating process of the fabrication method;

FIG. 5 is a cross section of the semiconductor device at a fourth stage in the fabricating process of the fabrication method;

FIG. 6 is a cross section of the semiconductor device at a fifth stage in the fabricating process of the fabrication method;

FIG. 7 is a cross section of the semiconductor device at a sixth stage in the fabricating process of the fabrication method;

FIG. 8 is a cross section of the semiconductor device at a seventh stage in the fabricating process of the fabrication method;

FIG. 9 is a cross section of the semiconductor device at an eighth stage in the fabricating process of the fabrication method;

FIG. 10 is a cross section of the semiconductor device at a ninth stage in the fabricating process of the fabrication method;

FIG. 11A is a cross section of the semiconductor device at a tenth stage in the fabricating process of the fabrication method;

FIG. 11B is an enlarged cross section of the semiconductor device as shown in FIG. 11A;

FIG. 12 is a cross section of the semiconductor device at a stage corresponding to FIG. 8 in another fabricating process of the fabrication method;

FIG. 13 is a cross section of the semiconductor device at a stage corresponding to FIG. 11A in said another fabricating process of the fabrication method;

FIG. 14 is a view similar to FIG. 1, showing the semiconductor device of another embodiment in accordance with the present invention;

FIG. 15A is a view similar to FIG. 1, showing a conventional semiconductor device; and

FIG. 15B is an enlarged view of the conventional semiconductor device as shown in FIG. 11A.

### DETAILED DESCRIPTION OF THE INVENTION

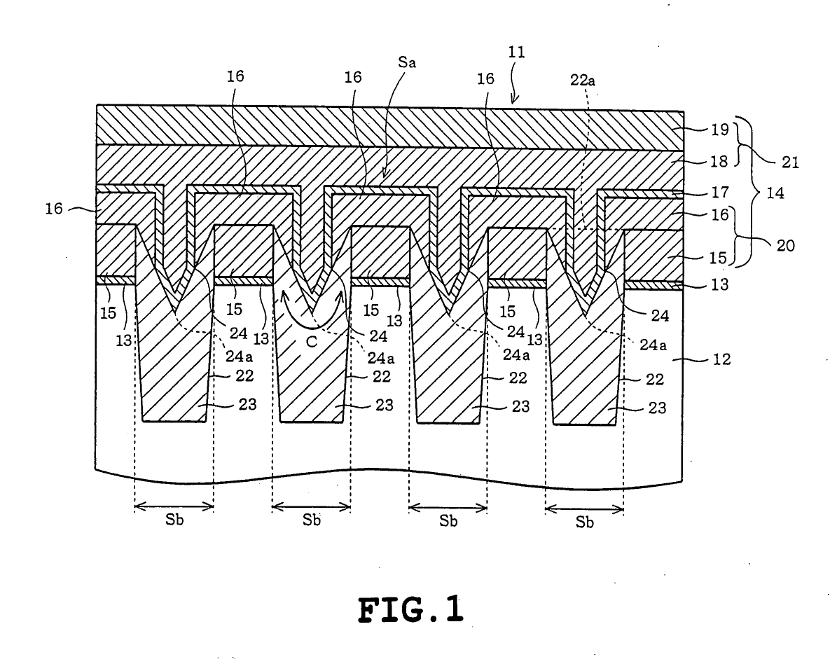

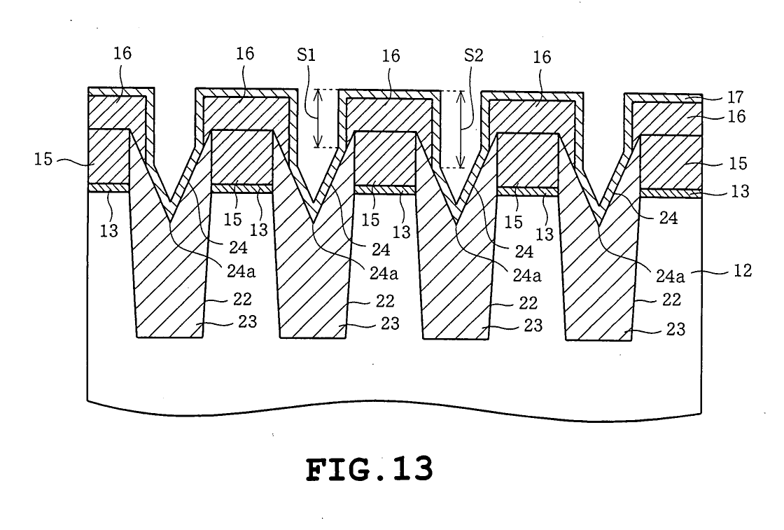

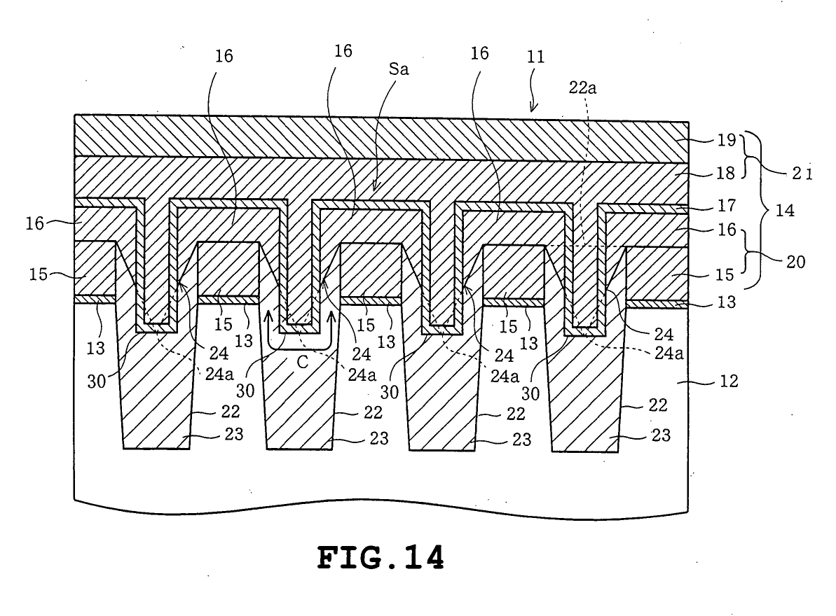

One embodiment of the present invention will be described with reference to FIGS. 1 to 13. In the embodiment, the invention is applied to a non-volatile memory such as a flash memory. More specifically, the invention is applied to a gate-electrode isolating structure of a memory cell region of the non-volatile memory 11. The invention may further be applied to a peripheral circuit region of the non-volatile memory 11, if possible.

### Gate Electrode Structure

A gate electrode of the memory cell region is isolated by STI and accordingly, the following describes sectional structures of a gate-electrode forming region Sa, an element isolation region Sb.

1. Sectional Structure of Gate-Electrode Forming Region Sa:

The non-volatile memory 11 comprises a silicon substrate 12 serving as a semiconductor substrate. In the gate-electrode forming region Sa, a gate oxide 13 serving as a gate insulating film is formed on the silicon substrate 12. A gate electrode 14 is formed on the gate oxide 13. The gate electrode 14 includes a first polycrystalline silicon film 15, a second polycrystalline silicon film 16, an oxide-nitride-oxide (ONO) film 17, a polycrystalline silicon film 18 and a Wsi film 19. The gate electrode 14 has a floating gate electrode 20 and a control gate electrode 21.

More specifically, the gate oxide 13 is formed on the silicon substrate 12. The first polycrystalline silicon film 15 is formed on the gate oxide 13. The second polycrystalline silicon film 16 is formed on the first polycrystalline silicon film 15. The ONO film 17 is formed on the second polycrystalline silicon film 16. The third polycrystalline silicon film 18 is formed on the ONO film 17. The Wsi film 19 is formed on the third polycrystalline silicon film 18.

The floating electrode 20 formed on the gate oxide 13 includes the first and second polycrystalline silicon films 15 and 16. The control gate electrode 21 includes the third polycrystalline silicon film 18 and WSi film 19. 2. Sectional structure of element isolation region Sb:

In the element isolation region Sb, trenches 22 serving as trenches are formed in the silicon substrate 12. Each trench 22 is formed so as to isolate the gate electrode in the memory cell region. An STI-TEOS film 23 (hereinafter, “TEOS film”) serving as an insulating film is embedded in each trench 22. Each TEOS film 23 has a top with opposite ends located higher than a top of the gate insulating film 13. The gate insulating films 13 are formed on opposite sides of each TEOS film 23. The top of each TEOS film 23 is recessed to be formed into a recess 24 having a generally V-shaped section extending downward from the tops of the adjacent first polycrystalline silicon films 15.

Each recess 24 is tapered so as to extend downward from an opening 22a of the trench 22 toward the center of the trench 22. The top of the TEOS film 23 and the opening 22a of the trench 22 are formed so as to be co-planar. On the TEOS film 23 are formed the second polycrystalline silicon film 16 and the ONO film 17 in turn. The third polycrystalline silicon film 18 is formed on the ONO film 17. The WSi film 19 is formed on the third polycrystalline silicon film 18.

The aforesaid second polycrystalline silicon film 16 is formed so as to extend over the element isolation region Sb. The floating gate electrode 20 has a larger width than the gate oxide 13 and includes a part extending along an inclined face of the recess 24 of the TEOS film 23. The floating gate electrode 20 is formed so as to have a generally T-shaped section.

### Fabricating Method

The method of fabricating the gate electrode of the non-volatile memory 11 will now be described. The embodiment employs a self-aligning process in which a part of the gate electrode is formed prior to an element isolation region forming step.

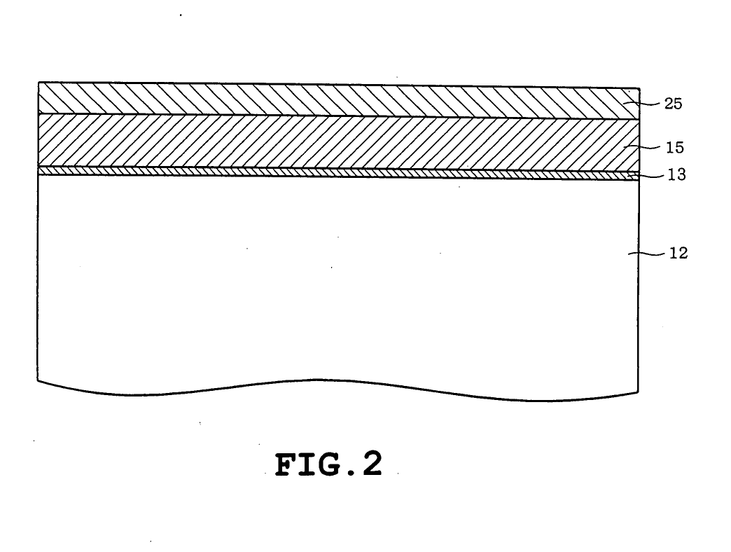

Firstly, as shown in FIG. 2, the gate oxide 13 having a film thickness of 10 nm, for example, is formed on the silicon substrate 12. The first polycrystalline silicon film 15 having a film thickness of 100 nm, for example, is formed on the gate oxide 13. A silicon-nitride (SiN) film 25 having a film thickness of 50 nm is formed on the first polycrystalline silicon film 15.

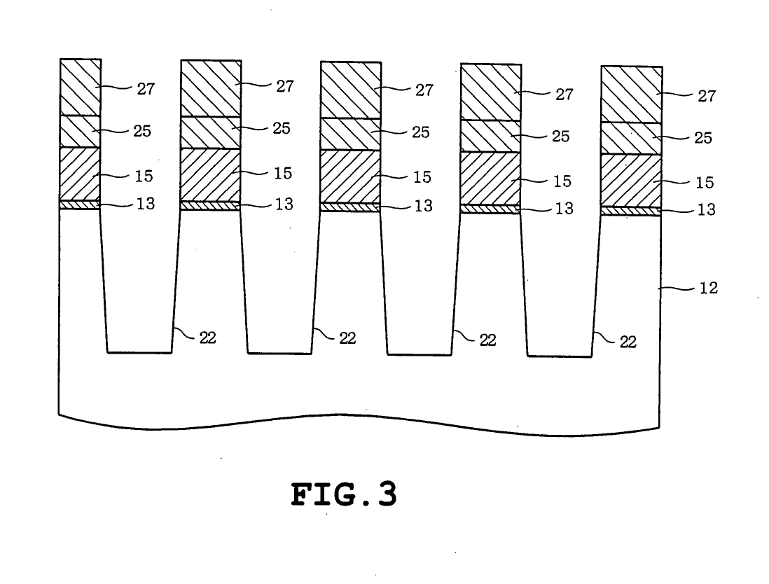

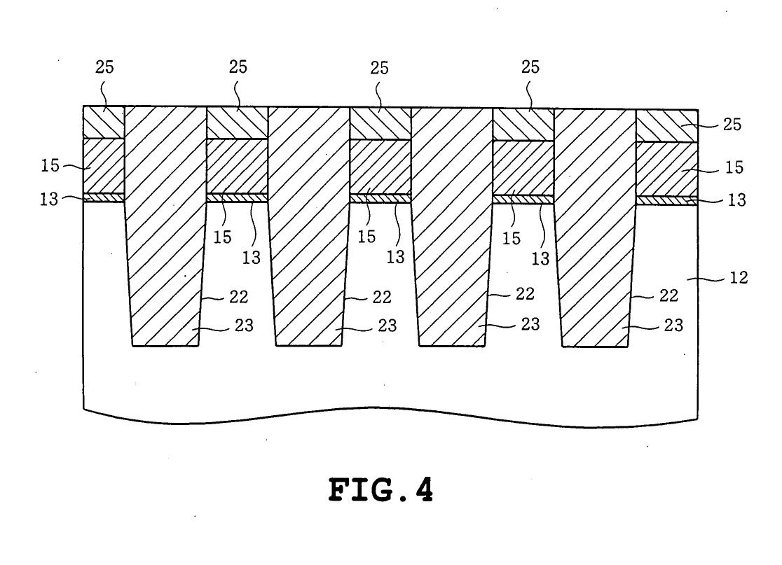

Then, as shown in FIG. 3, a resist pattern 27 is formed on the SiN film 25 by the photolithography process. An anisotropic etching is carried out for the SiN film 25, first polycrystalline silicon film 15, gate oxide 13 and silicon substrate 12 with the resist 27 serving as a mask, whereby the trench 22 is formed. Subsequently, as shown in FIG. 4, the resist 27 is removed, and a TEOS film 23 serving as an element isolating film is formed substantially over the entire upper surface of the silicon substrate 22. The TEOS film 23 is then embedded in the trenches 22 and the upper surface of the TEOS film 23 is flattened by the CMP process with the SiN film 25 serving as a stopper.

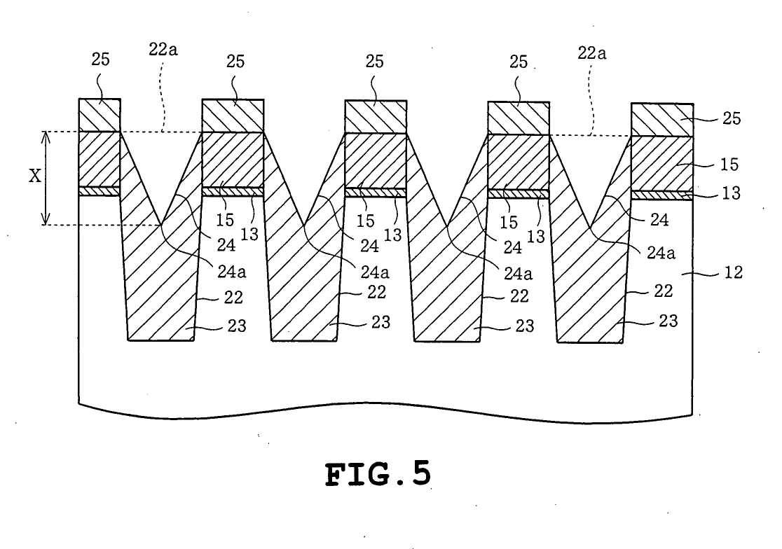

Subsequently, as shown in FIG. 5, the TEOS film 23 is etched with the SiN film 25 serving as a mask so as to be tapered. This etching process is carried out by a gas plasma RIE method, for example, under the conditions of 40 mTorr, 500 W, and C₄F₈/O₂/Ar=30/10/50 sccm. As a result, the V-shaped recess 24 is formed in the upper portion of the TEOS film 23. More specifically, the upper portion of the TEOS film 23 can be formed into a tapered shape, extending from the opening 22a of the trench 22 toward the center of the trench 22, whereupon the recess 24 can be formed in the V-shaped portion. In this case, since the recess 24 is formed in the TEOS film 23 with the SiN film 25 serving as a mask so as to have the V-shape, it can be formed without adversely affecting the characteristic of the first polycrystalline silicon film 15 as the floating gate electrode 20.

Alternatively, the TEOS film 23 may firstly be etched by the wet etching or etch back process so as to be recessed to a predetermined height (for example, to the upper side of the first polycrystalline silicon film 15) and thereafter, the TEOS film 23 may be formed into the V-shape by the RIE process executed under the foregoing conditions. Further, the recess 24 is formed so that the opening 22a thereof is located near a boundary face of the SiN film 25 and the first polycrystalline silicon film 15 or so that the opening 22a is located in a plane in which the first polycrystalline silicon film 15 is formed. The effect of reducing the parasitic capacitance becomes maximum when the recess 24 reaches the depth of the gate oxide 13. Thus, the effect of reducing parasitic capacitance becomes smaller as the recess 24 is shallow. The effect does not change even when the recess 24 is deepened exceeding the gate oxide 13. Accordingly, it is desirable that a lower end 24a of the V-shaped portion of the recess 24 is formed so that a lower end 24a of the V-shaped portion of the recess 24 is located as high as or lower than the gate oxide 13. For example, it is desirable that a distance X from the opening 22a to the lowest end of the recess is not less than 100 nm as shown in FIG. 5.

The position and angle of the lower end 24a of the recess 24 formed in the element isolation region Sb can be adjusted by changing the etching conditions when the change is necessary. Accordingly, the characteristic can further be improved when the lower end 24a of the V-shaped portion is formed under the aforesaid conditions.

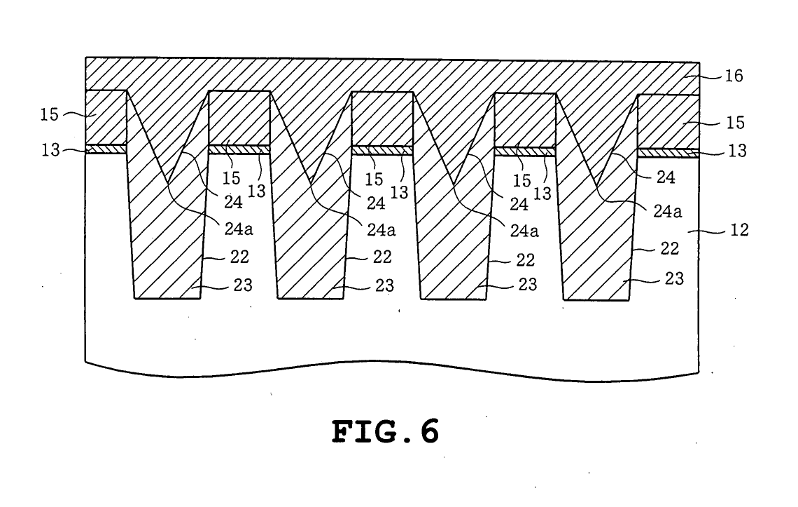

Subsequently, as shown in FIG. 6, the SiN film 25 is removed by wet etching and a natural oxide film (not shown) formed on the surface layer of the first polycrystalline silicon film 15 is removed by wet etching. The second polycrystalline silicon film 16 is made from the same material as the first polycrystalline silicon film 15 and is formed on the first polycrystalline silicon film 15. The second polycrystalline silicon film 16 is flattened by a CMP process so as to have a film thickness of about 100 nm on the first polycrystalline silicon film 16.

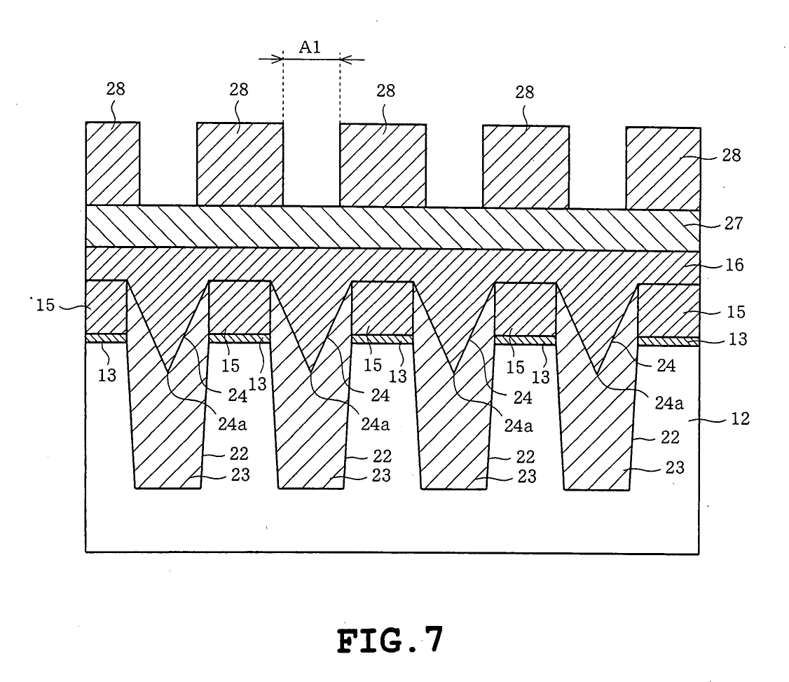

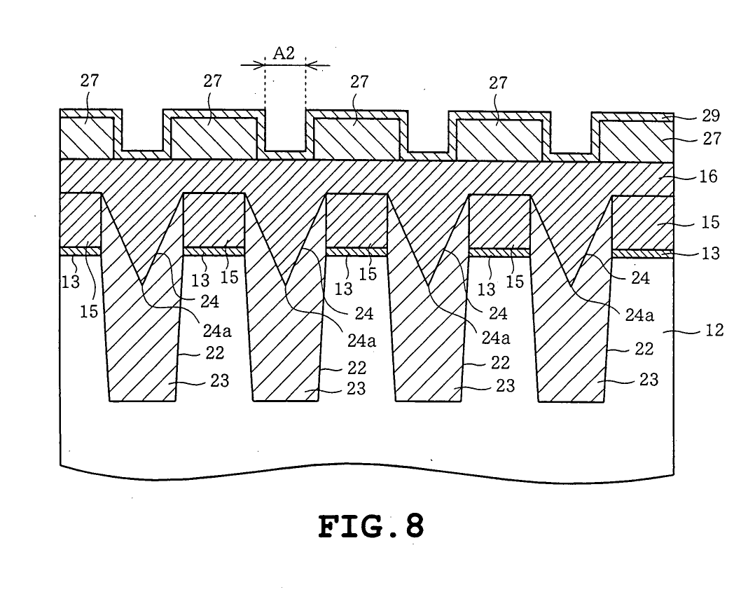

Still subsequently, as shown in FIG. 7, a hard mask 27 of a TEOS or BSG film is formed. A resist 28 is formed on the hard mask 27. For example, an opening width A1 is set to 200 nm as shown in FIG. 7. Subsequently, as shown in FIG. 8, the hard mask 27 is etched with the resist 28 serving as a mask, and a film 29 comprising a TEOS or BSG film is formed on the hard mask 27. More specifically, in the case of etching by RIE process (gas plasma), etching conditions for the hard mask 27 include 40 mTorr, 1400 W and CHF₃/CO=45/155 sccm. Then, the resist 20 is removed by an O₂ plasma process and further by a mixture of hydrogen peroxide and sulfuric acid and thereafter, the film 29 is formed on a portion where the resist 20 has been removed. Upon forming of the film 29, a width A2 between the film 29 and the memory cell adjacent to the film 29 is 100 nm, for example.

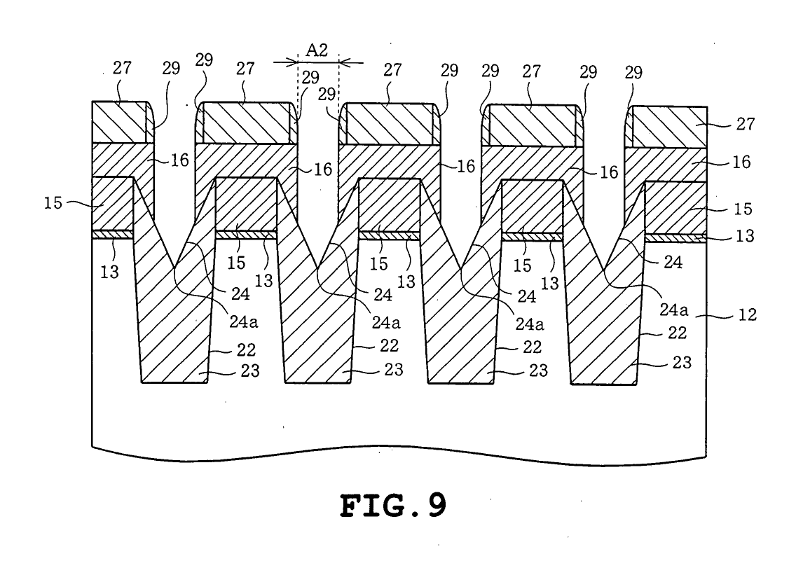

The second polycrystalline silicon film 16 is then etched with the hard mask 27 and film 29 serving as masks as shown in FIG. 9. This etching process has an etching time which is longer than the normal one by 50%. In this case, a distance between the second polycrystalline films adjacent to each other is 100 nm, which value is equal to the width A2 in FIG. 9. Consequently, the first and second polycrystalline silicon films 15 and 16 are physically isolated from each other between the memory cells adjacent to each other.

Further, the second polycrystalline silicon film 16 constituting the floating gate electrode 20 can be formed on the V-shaped recess 24 of the TEOS film 23 embedded in the trench 22. Still further, the first and second polycrystalline silicon films 15 and 16 constituting the floating gate electrode 20 are each formed into the T-shape.

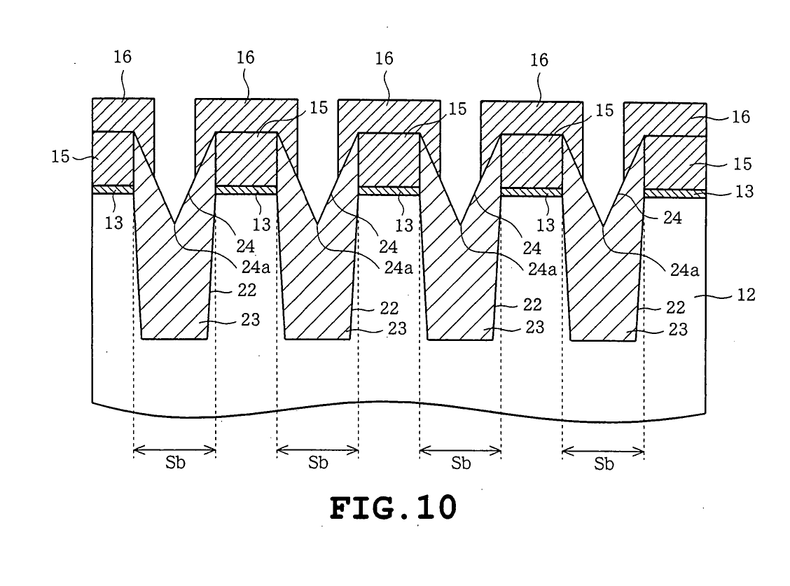

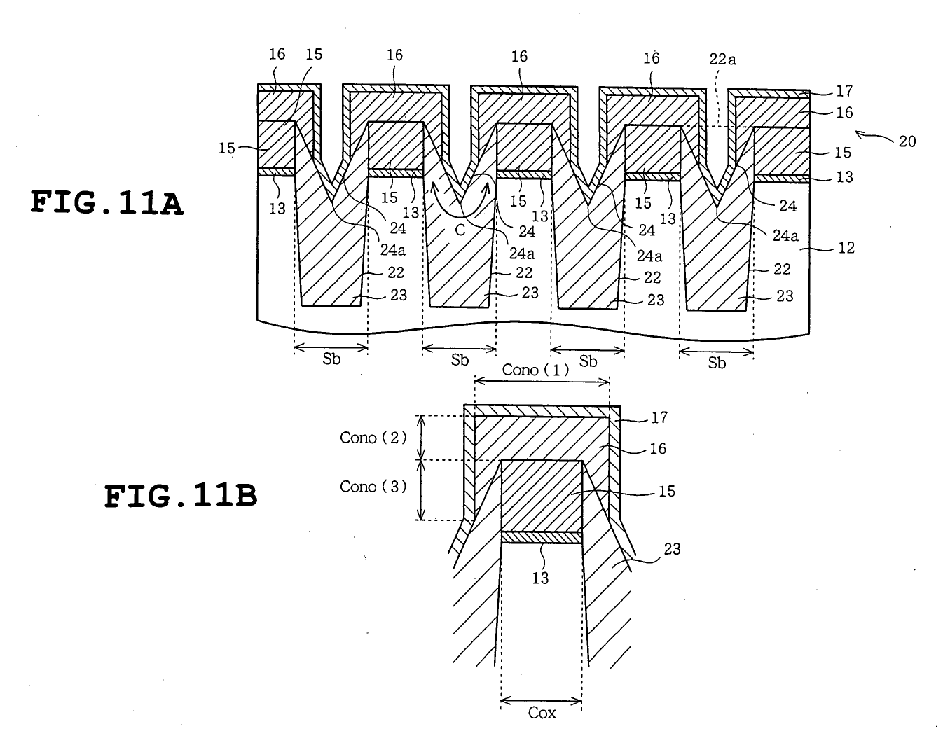

As shown in FIG. 10, the hard mask 27 and the film 29 are removed by the wet etching process under the condition having a high selectivity for the TEOS film 23 embedded in the trench 22. As shown in FIG. 11A, the ONO film comprising SiO₂ film/SiN film/SiO₂ film is formed over the top and side of the second polycrystalline silicon film 16. FIG. 11B is an enlarged view showing the ONO film 17 as shown in FIG. 11B. The ONO film 16 is formed on the second polycrystalline silicon film 16. A coupling ratio Cr in this case is obtained as:
Cᵣ=C₁/C₂ (1)
where
C₁=Cₒₙₒ(1)+Cₒₙₒ(2)+Cₒₙₒ(3), and
C₂=Cₒₙₒ(1)+Cₒₙₒ(2)+Cₒₙₒ(3)+Cₒₓ.
The value of the coupling ratio is ideally 1. The capacitance values of the capacitors Cₒₙₒ (1), Cₒₙₒ (2) and Cₒₙₒ (3) correspond to an area of a portion where the floating gate electrode 20 and the control gate electrode 21 with the ONO film 17 being interposed therebetween.

The value of Cₒₙₒ (1) indicates a capacitance value between the top of the floating gate electrode 20 and the third polycrystalline silicon film 18 which are opposed to each other with the ONO film 17 being interposed therebetween. The value of Cₒₙₒ (2) indicates a capacitance value a capacitance value between a portion of the side of the floating gate electrode 20 located above the top of the first polycrystalline silicon film 15 and the third polycrystalline silicon film 18 with the ONO film 17 being interposed therebetween. Further, the value of Cₒₙₒ (3) indicates a capacitance value between a portion of the side of the floating gate electrode 20 located below the top of the first polycrystalline silicon film 15 and the third polycrystalline silicon film 18 with the ONO film 17 being interposed therebetween. The value of Cₒₓ indicates a capacitance value of the capacitor of a portion of the floating gate electrode 20 opposed to the silicon substrate 12 with the gate insulating film 13 being interposed therebetween.

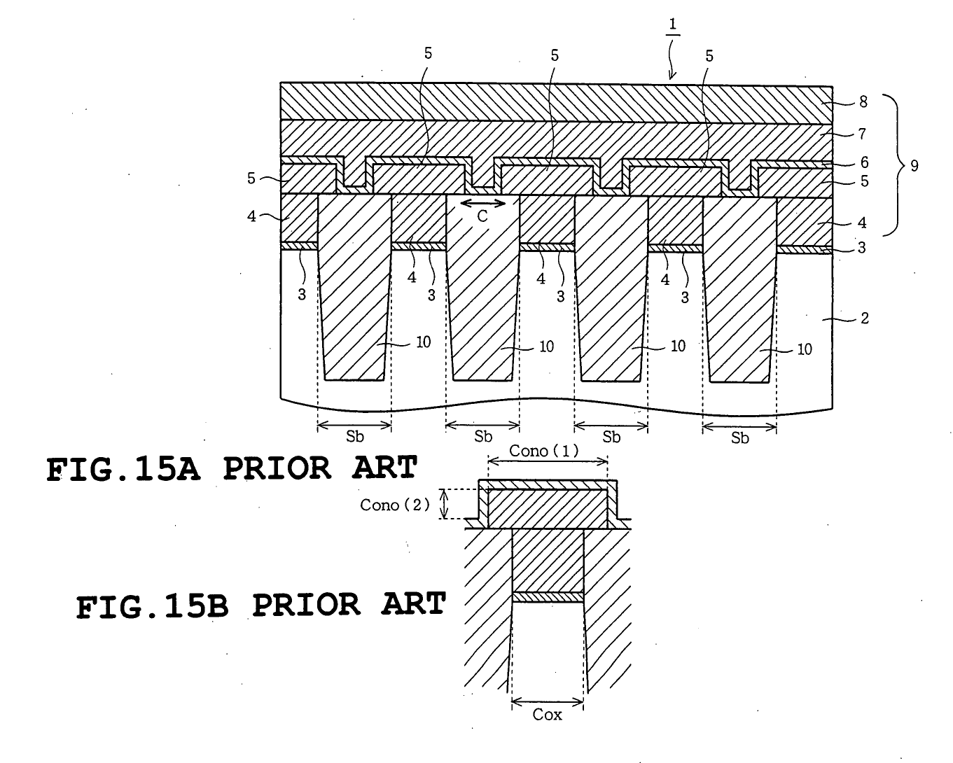

More specifically, the conventional structure as shown in FIG. 15A lacks a portion corresponding to Cₒₙₒ (3) as shown in the embodiment and accordingly, equation (1) indicating the coupling ratio Cᵣ has no term of Cₒₙₒ (3) such that the coupling ratio Cᵣ cannot take a large value.

In the embodiment, the element isolation region Sb is formed so that the V-shaped recess 24 is formed on the upper portion of the TEOS film 23 embedded in the trench 22. The ONO film 17 and the second polycrystalline silicon film 16 are formed so as to extend over the recess 24. Consequently, apart of the floating gate electrode 20 is formed on the recess 24 of the TEOS film 23. This construction can increase an area of the second silicon film 16 opposed to the third silicon film 18 with the ONO film 17 being interposed therebetween, thereby increasing the capacitance value of the capacitor.

It is considered that the capacitance value of the capacitor can be ensured by increasing the film thickness of the polycrystalline silicon film of the floating gate electrode 20 in the conventional structure as shown in FIG. 15A. In the foregoing embodiment, however, increasing the film thickness is not required, and both coupling ratio Cᵣ and capacitance value of the capacitor of the floating gate electrode 20 can simultaneously be increased without reduction in the embeddability of the TEOS film 23.

Still further, the parasitic capacitance C between adjacent floating gate electrodes 20 can be reduced by forming the upper portion of the TEOS film 23 into the V-shaped recess 24. More specifically, the adjacent floating gate electrodes 20 are electrically coupled together via the V-shaped recess 24 of the TEOS film 23. Consequently, the distance between the adjacent floating gate electrodes 20 can be increased and the parasitic capacitance C can be reduced. This technique is effective particularly to multi-value NAND non-volatile memories which are difficult to be controlled by a threshold control, thereby further improving the performance of a semiconductor device.

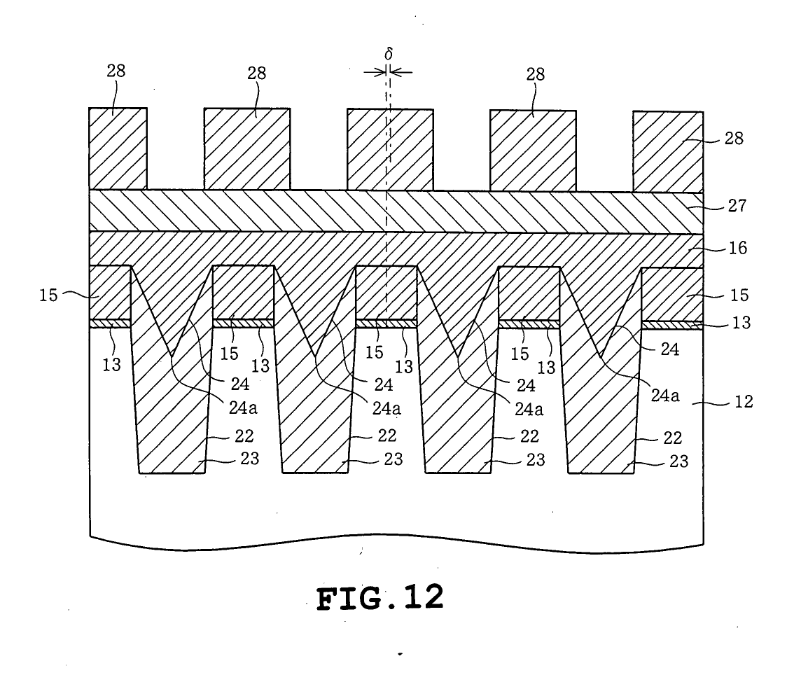

A pattern misalignment 6 of resist 28 sometimes occurs in the crosswise direction as viewed in FIG. 12 during the step of removing the second polycrystalline silicon film 16 (corresponding to FIG. 7). As a result, the second polycrystalline silicon film 16 is biased in the crosswise direction as viewed in FIG. 12. When the ONO film 17 has been formed, a contact area S1 is reduced between one side of the ONO film 17 and the second polycrystalline silicon film 16, and a contact area S2 is increased between the other side of the ONO film 17 and the second polycrystalline silicon film 16. Consequently, the increase and decrease in the area are denied by each other. When the semiconductor device is fabricated in the aforementioned process, adverse effects of variations in the coupling ratio Cᵣ and capacitance value of the capacitor can be reduced.

After formation of the ONO film 17, the third polycrystalline silicon film 18 is formed on the ONO film 17. The WSi film 19 is formed on the third polycrystalline silicon film 18. Subsequently, a predetermined gate electrode configuration is formed (see FIG. 1). An interlayer insulating film (not shown) is deposited in a subsequent step. Detailed description of subsequent steps will be eliminated since these steps are generally known. A contact hole is formed in the interlayer insulating film so that a diffused layer is exposed. A metal such as tungsten is embedded in the contact hole so that a contact plug (not shown) is formed. A wiring layer (not shown) is then formed on the interlayer insulating film. The wiring layer is then connected to the contact plug. The non-volatile memory 11 is thus fabricated through the foregoing process.

As described above, the TEOS film 23 constituting the element isolation region Sb has the recess 24 formed in the upper portion thereof and having a V-shaped section. Consequently, the parasitic capacitance C between the memory cells can be reduced even when an area of inner circuit is decreased with reduction in the circuit design rules such that the distance between the adjacent memory cells is reduced. The recess 24 is formed into the V-shape in the foregoing embodiment. However, the invention should not be limited to the V-shaped recess with an acute lower end. The recess 24 may be formed into a generally U-shape and may have a smoothly curved lower end.

Further, since the floating gate electrode 20 is formed on the upper portion of the recess 24 of the TEOS film 23, desired coupling ratio Cr and capacitance value of the capacitor of the floating gate electrode 20 can be obtained without increase in the surface area of the side of the first polycrystalline silicon film 15 and increase in the height of the floating gate electrode 20.

It has conventionally been suggested that the upper surface of the TEOS film 23 is flattened and etched deep into a rectangular region, on which the ONO film 17 is formed so that the parasitic capacitance between the adjacent floating gate electrodes 20 is reduced. However, this conventional method is undesirable since it increases the number of steps in the case where the element isolation region Sb is formed. In the foregoing embodiment, however, the parasitic capacitance between the floating gate electrodes 20 can also be reduced without increase in the number of fabrication steps.

The invention should not be limited to the foregoing embodiment but may be modified or expanded as follows: after the recess 24 has been formed, a generally rectangular portion 30 may be formed near the lower end 24a of the recess 24, whereby the recess 24 is completed. More specifically, the second polycrystalline silicon film 16 is formed after the upper portion of the TEOS film 23 has been formed so as to have the V-shaped section. The second polycrystalline silicon film 16 is etched and the rectangular portion 30 is then formed in the recess 24 with an upper-end inclined portion of the V-shaped TEOS film 23. Thereafter, the ONO film 17 is formed. Although a large effect of reducing the parasitic capacitance C can be achieved by forming the TEOS film 23 into the V-shape in the foregoing embodiment, further reduction in the parasitic capacitance C can be achieved from the modified form.

Regarding the fabricating method, the foregoing embodiment includes the step of forming a part of the gate electrode in a self-aligning manner prior to the step of forming the element isolation region. However, any process may be carried out so long as the upper portion of the TEOS film 23 is formed into the V-shape. Only one condition for the upper side of the TEOS film 23 is that the upper side of the TEOS film 23 is formed with the recess 24 extending toward the silicon substrate 12.

The invention may be applied to NAND or NOR flash memories. Further, although the V-shape of the recess 24 is shown acute in the figures, the V-shape may be obtuse, instead.

The foregoing description and drawings are merely illustrative of the principles of the present invention and are not to be construed in a limiting sense. Various changes and modifications will become apparent to those of ordinary skill in the art. All such changes and modifications are seen to fall within the scope of the invention as defined by the appended claims.

1. A semiconductor device comprising:
a semiconductor substrate having an upper face;
a plurality of trenches formed in the semiconductor substrate;
an element isolating film embedded in each trench and having a top located higher than the upper face of the semiconductor substrate;
a gate insulating film formed on the semiconductor substrate so as to be located between the element isolating films adjacent to each other; and
a gate electrode formed on the gate insulating film and having a top located higher than the top of the element isolating film, wherein the element isolating film has a recess formed on the top thereof so that the recess extends toward the semiconductor substrate.

2. The semiconductor device according to claim 1, wherein the gate electrode includes a floating gate electrode formed on the gate insulating film and a control gate electrode formed on the floating gate electrode, the floating gate electrode having an upper portion extending over the recess of the element isolating film formed so as to be adjacent to the floating gate electrode.

3. The semiconductor device according to claim 2, wherein the floating gate electrode includes first and second polycrystalline silicon films stacked in turn so as to have a section formed into a T-shape.

4. The semiconductor device according to claim 1, wherein the recess of the element isolating film has a bottom formed so as to be located as high as or lower than the gate insulating film.

5. The semiconductor device according to claim 2, wherein the recess of the element isolating film has a bottom formed so as to be located as high as or lower than the gate insulating film.

6. The semiconductor device according to claim 1, wherein the recess of the element isolating film extends from an opening of the trench toward a sectional center of the element isolating film so as to have a tapered shape and a V-shaped section.

7. The semiconductor device according to claim 2, wherein the recess of the element isolating film extends from an opening of the trench toward a sectional center of the element isolating film so as to have a tapered shape and a V-shaped section.

8. The semiconductor device according to claim 4, wherein the recess of the element isolating film extends from an opening of the trench toward a sectional center of the element isolating film so as to have a tapered shape and a V-shaped section.

9. The semiconductor device according to claim 5, wherein the recess of the element isolating film extends from an opening of the trench toward a sectional center of the element isolating film so as to have a tapered shape and a V-shaped section.

10. The semiconductor device according to claim 1, wherein the recess of the element isolating film includes a lower end side in which a rectangular portion having a rectangular section is formed.

11. The semiconductor device according to claim 2, wherein the recess of the element isolating film includes a lower end side in which a rectangular portion having a rectangular section is formed.

12. The semiconductor device according to claim 4, wherein the recess of the element isolating film includes a lower end side in which a rectangular portion having a rectangular section is formed.

13. The semiconductor device according to claim 5, wherein the recess of the element isolating film includes a lower end side in which a rectangular portion having a rectangular section is formed.

14. A method of fabricating a semiconductor device, comprising:
forming a trench in a semiconductor substrate;
embedding an insulating film in the trench; and
forming a recess in a top of the insulating film.

15. A method of fabricating a semiconductor device, comprising:
forming a gate insulating film on a semiconductor substrate;
forming a trench in the semiconductor substrate and the gate insulating film so that a gate electrode is formed on the gate insulating film;
embedding an insulating film in the trench; and
forming a recess in a top of the insulating film.
